(19) United States
(12) Patent Application Publication
(10) Pub. No.: US 2016/0356477 A1
(43) Pub. Date: Dec. 8, 2016

(54) PHASE-CHANGE HEAT DISSIPATING DEVICE AND LAMP

(71) Applicant: ARC Solid-State Lighting Corporation, New Taipei City (TW)

(72) Inventor: Hai Lan, New Taipei City (TW)

(21) Appl. No.: 14/818,935

(22) Filed: Aug. 5, 2015

(30) Foreign Application Priority Data
Jun. 5, 2015 (TW) 104118279

(51) Int. Cl. F21V 29/51; F21V 29/71; F21V 29/76; H05K 7/20

(52) U.S. Cl. CPC F21V 29/51; H05K 7/20309; H05K 7/20318; F21V 29/713; F21V 29/76; F21Y 2101/02

(57) ABSTRACT

A phase-change heat dissipating device includes a heat absorbing body, a heat dissipation body and two tubes. The heat absorbing body is filled with a working fluid. The heat dissipation body has a first end and a second end that are adjacent to two sides of the heat absorbing body, respectively. The tubes connect the heat absorbing body and the heat dissipation body. When parts of the heat dissipation body is located higher than the heat absorbing body and the working fluid absorbs the heat energy generated from a heat source, the working fluid is evaporated from a liquid phase to a gas phase and flows into the heat dissipation body through the tubes. The working fluid locating in the heat dissipation body is condensed from the gas phase into the liquid phase and flows to the heat absorbing body through the tubes.

### CROSS-REFERENCE TO RELATED APPLICATIONS

This non-provisional application claims priority under 35 U.S.C. §119(a) on Patent Application No(s). 104118279 filed in Taiwan, R.O.C. on Jun. 5, 2015, the entire contents of which are hereby incorporated by reference.

### TECHNICAL FIELD

The disclosure relates to a phase-change heat dissipating device and a lamp, more particularly to a phase-change heat dissipating device and a lamp that can be installed in different positions.

### BACKGROUND

Light emitting diodes (LEDs) have superior characteristics such as low power consumption, high-energy conversion efficiency, long lifespan, and lack of mercury pollution, thereby taking the advantage over incandescent lights. However, the conventional LED has a deficiency in its capability of heat dissipation, thus the incandescent light can not be totally replaced by the conventional LED yet.

For example, a heat sink is usually used for transferring heat energy away from a conventional LED lamp. However, the heat sink alone is not sufficient to remove enough heat energy generated from the LEDs. Thus, developers constantly try to improve the heat dissipating efficiency of the heat dissipating device in order to cool the LEDs. For example, the heat dissipating efficiency of the heat dissipating device can be improved by using the principle of phase-change heat dissipation.

However, even though the heat dissipating efficiency of the heat dissipating device is able to be improved according to the principle of the phase-change heat dissipation, but once the heat dissipating device, which is placed upside down, is unable to exert phase-change heat dissipation because gas tends to rise up, thereby restricting how the lamp including the phase-change heat dissipating device is installed and illuminated. That is, the lamp which is exclusively designed for illuminating downward to the ground is not adapted for illuminating upward, leftward or rightward. Therefore, developers try to solve the problem that the position of the lamp with the phase-change heat dissipating device is restricted.

### SUMMARY

In one embodiment, a phase-change heat dissipating device includes a heat absorbing body, at least one heat dissipation body and at least two tubes. The heat absorbing body is for being in thermal contact with at least one heat source. The heat absorbing body is filled with a working fluid. The heat dissipation body has a first end and a second end. The first end and the second end of the heat dissipation body are adjacent to two sides of the heat absorbing body that are different from each other, respectively. Two tubes connect the heat absorbing body and the heat dissipation body. When parts of the heat dissipation body are located higher than the heat absorbing body and the working fluid absorbs the heat energy generated from the heat source, the working fluid is evaporated from a liquid phase to a gas phase and flows into the heat dissipation body through one of the two tubes for dissipating heat. The working fluid which is located in the heat dissipation body is condensed from the gas phase into the liquid phase and flows to the other of the two tubes.

In another embodiment, a phase-change heat dissipating device includes a heat absorbing body, at least two heat dissipation bodies and a plurality of tubes. The heat absorbing body is for being in thermal contact with a heat source. The heat absorbing body is filled with a working fluid. The two heat dissipation bodies are adjacent to two sides of the heat absorbing body that different from each other, respectively. The tubes connect the heat absorbing body and the two heat dissipation bodies. When one of the heat dissipation bodies is located higher than the heat absorbing body and the working fluid absorbs the heat energy generated from the heat source, the working fluid is evaporated from a liquid phase to a gas phase and flows into one of the two heat dissipation bodies through one of the tubes for dissipating heat. The working fluid which is located in one of the two heat dissipation bodies is condensed from the gas phase into the liquid phase and flows to heat absorbing body through one of the tubes.

In yet another embodiment, a lamp includes a case, at least one phase-change heat dissipating device and at least one light source. The case has a space and a light transmitting part which is connected to a side of the space. The at least one phase-change heat dissipating device is disposed in the space. The phase-change heat dissipating device includes a heat absorbing body, at least one heat dissipation body and at least two tubes. The heat absorbing body is filled with a working fluid. The heat dissipation body has a first end and a second end. The first end and the second end of the heat dissipation body are adjacent to two sides of the heat absorbing body that are different from each other. The two tubes connect the heat absorbing body and the heat dissipation body. The light source is in thermal contact with the heat absorbing body, and the light source is exposed from the light transmitting part. When parts of the heat dissipation body is located higher than the heat absorbing body and the working fluid absorbs the heat energy generated from the light source, the working fluid is evaporated from a liquid phase to a gas phase and flows into the heat dissipation body though one of the two tubes for dissipating heat. The working fluid which is located in the heat dissipation body is condensed from the gas phase into the liquid phase and flows to the heat absorbing body through the other one of the two tubes.

In yet another embodiment, a lamp includes a case, at least one phase-change heat dissipating device and at least one light source. The case has a space and a light transmitting part which is connected to the space. The phase-change heat dissipating device is disposed in the space. The phase-change heat dissipating device includes a heat absorbing body, at least two heat dissipation bodies and a plurality of tubes. The heat absorbing body is for being in thermal contact with a heat source. The heat absorbing body is filled with a working fluid. The two heat dissipation bodies are adjacent to two sides of the heat absorbing body that are different from each other. The tubes connect the heat absorbing body and the two heat dissipation bodies. The light source is in thermal contact with the heat absorbing body, and the light source is exposed from the light transmitting part. When one of the heat dissipation bodies is located higher than the heat absorbing body and the working fluid absorbs the heat energy generated from the light source, the working fluid is evaporated from a liquid phase to a gas phase and flows into one of the two heat dissipation bodies through one of the tubes for dissipating heat. The working fluid which is located in one of the two heat dissipation bodies is condensed from the gas phase into the liquid phase and flows to the heat absorbing body through one of the tubes.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of a lamp according to a first embodiment of the disclosure;

FIG. 2 is a perspective view of a phase-change heat dissipating device and a light source according to FIG. 1 of the disclosure;

FIG. 3 is a cross-sectional view of the phase-change heat dissipating device and the light source according to FIG. 2 of the disclosure;

FIG. 4A is a schematic view of the lamp of FIG. 1 mounted on a ceiling;

FIG. 4B is a schematic view of the lamp of FIG. 1 mounted on a upright wall;

FIG. 5 is a cross-sectional view of the phase-change heat dissipating device according to a second embodiment of the disclosure;

FIG. 6 is a perspective view of the phase-change heat dissipating device and the light source according to a third embodiment of the disclosure;

FIG. 7 is a cross-sectional view of the phase-change heat dissipating device and the light source according to FIG. 6 of the disclosure;

FIG. 8 is a cross-sectional view of the phase-change heat dissipating device and the light source according to a fourth embodiment of the disclosure;

FIG. 9 is a perspective view of the phase-change heat dissipating device and the light source according to a fifth embodiment of the disclosure; and

FIG. 10 and FIG. 11 are cross-sectional views of the phase-change heat dissipating device and the light source from different viewpoints according to the fifth embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

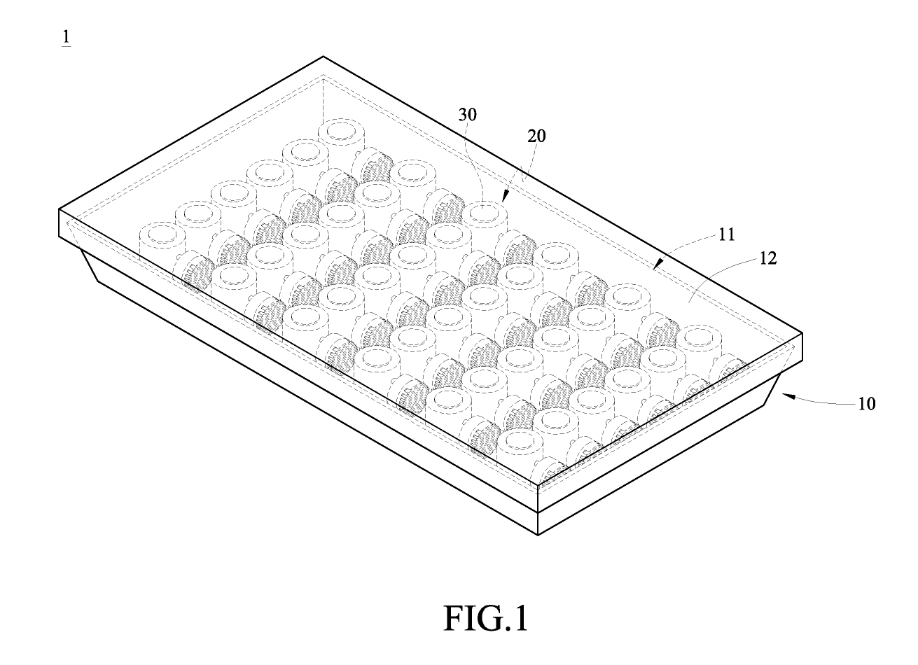

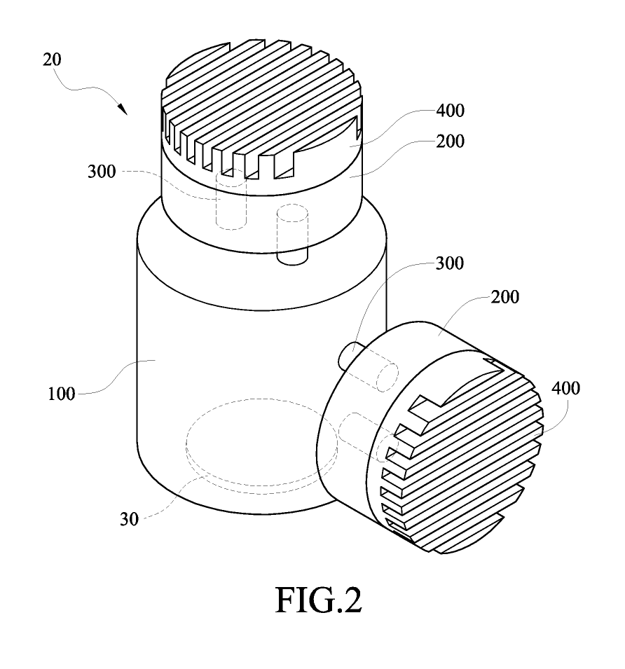

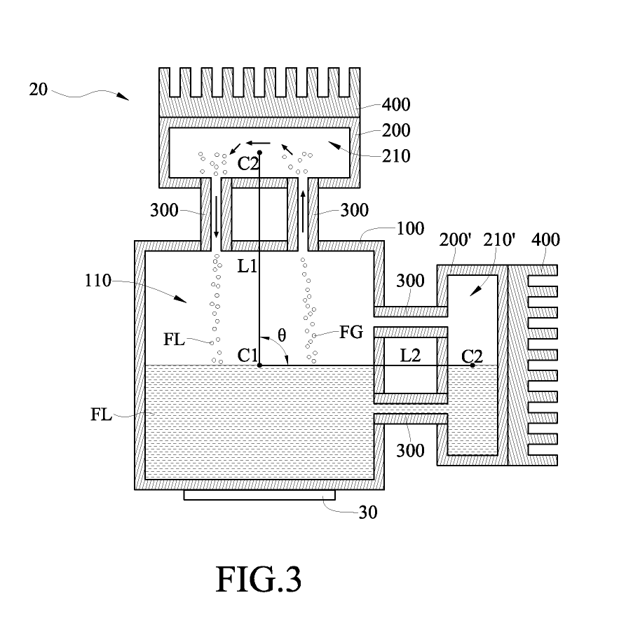

Please refer to FIG. 1 to FIG. 3. FIG. 1 is a perspective view of a lamp according to a first embodiment of the disclosure. FIG. 2 is a perspective view of a phase-change heat dissipating device and a light source according to FIG. 1 of the disclosure. FIG. 3 is a cross-sectional view of the phase-change heat dissipating device and the light source according to FIG. 2 of the disclosure. In this embodiment, the lamp 1 includes a case 10, a plurality of phase-change heat dissipating devices 20 and a plurality of light sources 30.

The case 10 has a space 11 and a light transmitting part 12 which is connected to a side of the space 11. The light transmitting part 12 is made of materials including, but not limited to, glass or plastic capable of being pervious to light.

The phase-change heat dissipating devices 20 are located in the space 11 and fixed in the case 10. Each phase-change heat dissipating device 20 includes a heat absorbing body 100, two heat dissipation bodies 200 and 200′ and a plurality of tubes 300. The heat absorbing body 100 is made of, for example, metal, graphite or ceramics.

The heat absorbing body 100 has a first chamber 110. The first chamber 110 is filled with a liquid-phase working fluid FL. In this embodiment, the liquid-phase working fluid FL is, for example, water. In other embodiments, the liquid-phase working fluid FL is, for example, refrigerant, methanol, ethanol, ethyl ether or some other liquid materials which are for improving thermal conductivity.

The heat dissipation bodies 200 and 200′ are made of, for example, metal, graphite or ceramics. The heat dissipation body 200 has a second chamber 210, and the heat dissipation body 200′ has a second chamber 210′. The heat dissipation bodies 200 and 200′ are, for example, cylindrical type and adjacent to two sides of the heat absorbing body 100, respectively. In this embodiment, the heat dissipation bodies 200 and 200′ are adjacent to two sides of the heat absorbing body 100 that are adjacent to each other, respectively. That is, one of the heat dissipation bodies 200 is, for example, disposed above the heat absorbing body 100, and the heat dissipation body 200′ is, disposed on the right side of the heat absorbing body 100, as shown in FIG. 3. More precisely, the two central points C2 of the two heat dissipation bodies 200 and 200′ and the central point C1 of the heat absorbing body 100 form two connecting lines L1 and L2, respectively, and an angle θ formed between the two connecting lines L1 and L2 is substantially a right angle. That is, the angle θ is, for example, slightly greater or less than a right angle. In other embodiments (not shown), two heat dissipation bodies are adjacent to two sides of the heat absorbing body that are opposite to each other, respectively. That is, for example, one of the heat dissipation bodies is disposed on the left side of the heat absorbing body, and the other one of the heat dissipation bodies is disposed on the right side of the heat absorbing body.

In this embodiment, the quantity of the tubes 300 is four. The four tubes can be divided into two pairs. One pair of the tubes 300 connect the heat absorbing body 100 and the heat dissipation body 200, and the other pair of the tubes 300 connect the heat absorbing body 100 and the heat dissipation body 200′, allowing the first chamber 110 to be connected the two second chambers 210 and 210′. In detail, two of the tubes 300 connect the heat absorbing body 100 and the heat dissipation body 200 which is disposed above the heat absorbing body 100. The other two of the tubes 300 connect the heat absorbing body 100 and the heat dissipation body 200′ which is located at the right side of the heat absorbing body 100. In addition, at least one of the tubes 300 is partially disposed higher than a liquid level of the liquid-phase working fluid FL, so that the gas-phase working fluid FG is able to flow upward into the heat dissipation body 200 or the heat dissipation body 200′.

In addition, the phase-change heat dissipating device 20 further includes two heat sinks 400. The two heat sinks 400 are in thermal contact with the heat dissipation bodies 200 and 200′ for improving the efficiency of heat dissipation of the phase-change heat dissipating device 20.

The light source 30 is, for example, a light emitting diode or a tungsten lamp. The light source 30 is in thermal contact with the heat absorbing body 100, and the light source 30 is adjacent to one of the heat dissipation bodies 200 and 200′ and opposite to the other one of the heat dissipation bodies 200 and 200′. The light sources 30 are exposed to the outside of the lamp 1 through the light transmitting part 12.

Heat dissipation principle of the lamp 1 will be depicted in the following description. As shown in FIG. 3, when the light source 30 is turned on and one of the heat dissipation bodies 200 and 200′ is disposed higher than the heat absorbing body 100, heat energy generated from the light source 30 is able to be transmitted to the working fluid FL in first chamber 110 via the heat absorbing body 100. The working fluid FL absorbs the heat energy generated from the light source 30 to be evaporated from a liquid phase to a gas phase. The gas-phase working fluid FG rises up and flows into the second chamber 210 of the heat dissipation body 200 through one of the tubes 300 according to physical characteristic of gas, and heat energy is dissipated to the external environment through the heat dissipation body 200 and the heat sink 400. Then, in the second chamber 210, the gas-phase working fluid FG is gradually condensed into liquid-phase working fluid FL during the dissipation of heat energy before flows to the first chamber 110 of the heat absorbing body 100 through one of the tube 300 to form a cooling circulation automatically. Accordingly, the heat energy generated from the light source 30 is able to be automatically removed through the cooling circulation.

In addition, because the aforementioned cooling circulation is automatically formed according to the physical characteristics of gas and without any assistance of a pump or some other active elements, thus the power consumption of the phase-change heat dissipating device 20 is reduced.

Moreover, as shown in FIG. 3, when the heat dissipation body 200′ and the tubes 300 connected thereto are located lower than a liquid level of the working fluid FL, parts of the working fluid FL in the heat absorbing body 100 may flow into the heat dissipation body 200′ due to the gravity. Thus, for example, in other embodiments, one-way valves are mounted in the tubes 300 for restricting the flow direction of the working fluid. In yet another embodiment, switching valves are mounted on the tubes 300 for controlling conditions of the working fluid in the tube 300. In such a case, the switching valve is able to control whether the working fluid can flow through the switching valve. Accordingly, the working fluid FL flowing into the heat dissipation body 200′ can be controlled, so that the heat absorbing body 100 has a sufficient amount of the working fluid FL to perform desired thermal conductivity.

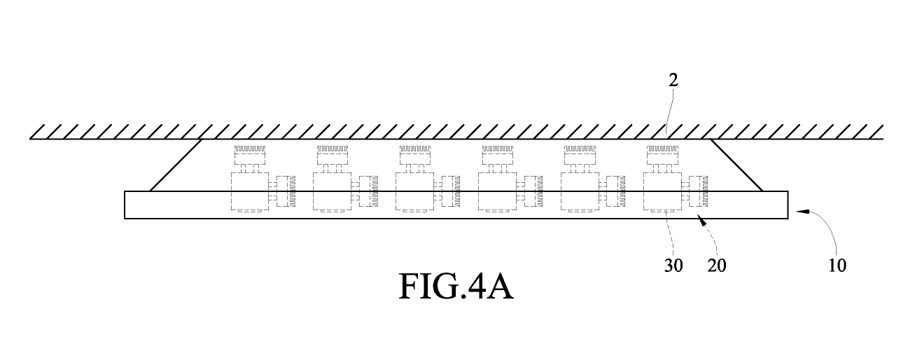

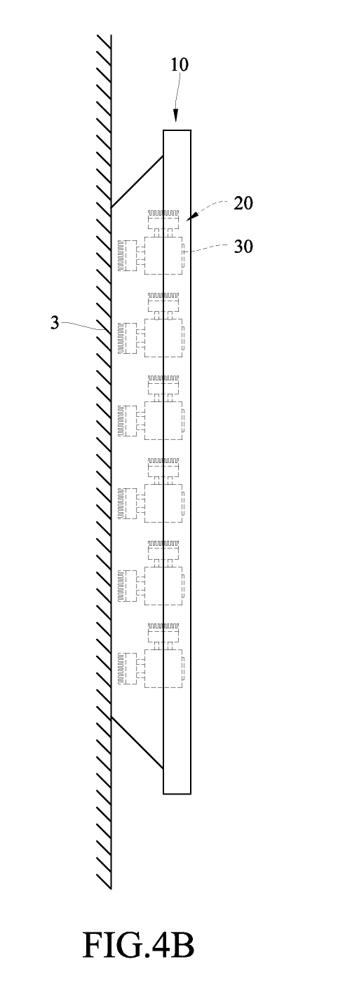

In this embodiment, the phase-change heat dissipating device 20 has two heat dissipation bodies 200 and 200′ which are disposed on two sides of the heat absorbing body 100 that are adjacent to each other, respectively. Thus, the lamp 1 can be disposed at two different positions or directions. In detail, please refer to FIGS. 4A-4B. FIG. 4A is a schematic view of the lamp of FIG. 1 mounted on a ceiling. FIG. 4B is a schematic view of the lamp of FIG. 1 mounted on an upright wall. As shown in FIG. 4A, the light source 30 is oriented to be at a first position. That is, the light source 30 is able to illuminate downward when the lamp 1 is mounted on a ceiling 2. Because the heat dissipation body 200 of the phase-change heat dissipating device 20 is disposed above the heat absorbing body 100, when the lamp 1 is oriented to be at the first position and in operation, the aforementioned cooling circulation is automatically performed in the heat dissipation body 200 and the heat absorbing body 100 to remove the heat energy generated from the light source 30 as shown in FIG. 3.

As shown in FIG. 4B, the lamp 1 is oriented to be at a second position, that is, the lamp 1 is mounted on an upright wall 3 and the light source 30 illuminates the right side of the upright wall 3. When the lamp 1 is oriented at the second position and in operation, the heat dissipation body 200′ of the phase-change heat dissipating device 20 is located above the heat absorbing body 100, thus the aforementioned cooling circulation is automatically performed in the heat dissipation body 200′ and the heat absorbing body 100 to remove the heat energy generated from the light source 30. Therefore, in this embodiment, the lamp 1 is able to perform the cooling circulation automatically when being at the first position and the second position, thereby reducing the restriction on where the lamp is disposed.

For example, the aforementioned phase-change heat dissipating device 20 can be used in field of the lighting. In other embodiments, the aforementioned phase-change heat dissipating device 20 also can be used in fields of the monitor, desktop, portable computer or server.

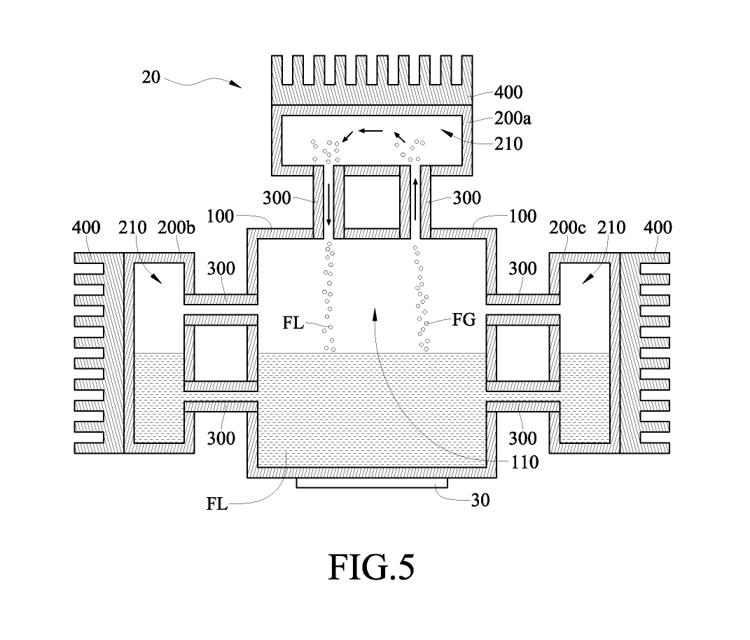

In this embodiment, the quantity of the heat dissipation body 200 of the phase-change heat dissipating device 20 is two, but the present disclosure is not limited to the quantity of the heat dissipation body 200. In other embodiments, the quantity of the heat dissipation body 200 is greater than three. Please refer to FIG. 5, which is a cross-sectional view of the phase-change heat dissipating device according to a second embodiment of the disclosure.

As shown in FIG. 5, in this embodiment, the quantity of the heat dissipation bodies 200a, 200b and 200c is three. The three heat dissipation bodies 200a, 200b and 200c are located at different sides of the heat absorbing body 100. In detail, the heat dissipation body 200a and the light source 30 are disposed on two sides of the heat absorbing body 100 that are opposite to each other. The heat dissipation body 200b and the heat dissipation body 200c are disposed between the light source 30 and the heat dissipation body 200a and disposed on two sides of the heat absorbing body 100 that are opposite to each other. Therefore, lamp 1 can be oriented to be at least three positions.

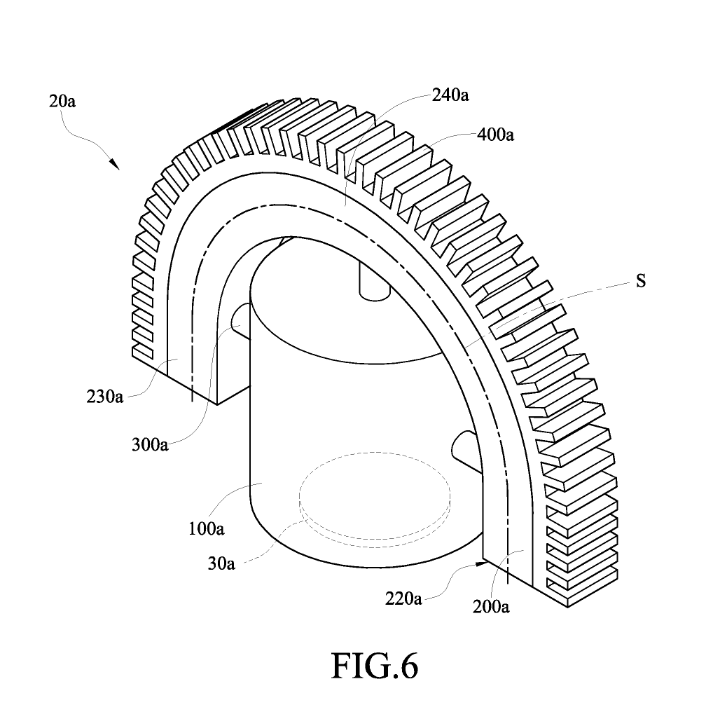

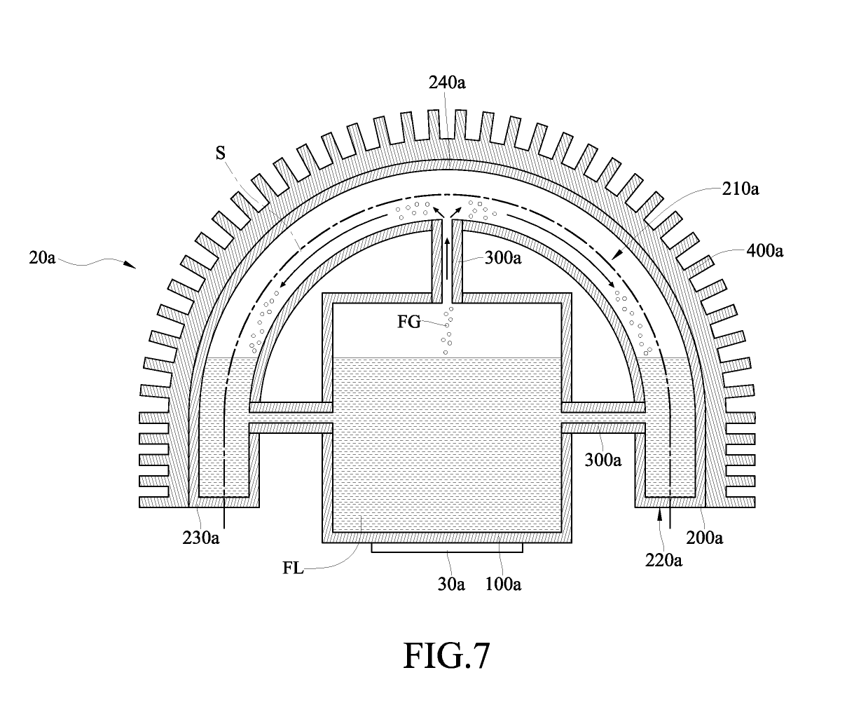

In the above embodiments, the quantity of the heat dissipation bodies 200a and 200b and 200c is three, allowing the lamp 1 to be oriented in different directions and positions, but the disclosure is not limited thereto. In other embodiments, the quantity of the heat dissipation body 200 is one, and the lamp 1 can be oriented to be in different directions. Please refer to FIG. 6 and FIG. 7. FIG. 6 is a perspective view of the phase-change heat dissipating device and the light source according to a third embodiment of the disclosure. FIG. 7 is a cross-sectional view of the phase-change heat dissipating device and the light source according to FIG. 6 of the disclosure. In this embodiment, the phase-change heat dissipating device 20a includes a heat absorbing body 100a, a heat dissipation body 200a and a plurality of tubes 300a.

The heat absorbing body 100a is made of, for example, metal, graphite, ceramics or some other materials having a heat-transfer capability. The heat absorbing body 100a has a first chamber 110a. The first chamber 110a is filled with the liquid-phase working fluid FL. In this embodiment, the liquid-phase working fluid FL is, for example, water. In other embodiments, the working fluid FL is, for example, refrigerant, methanol, ethanol, ethyl ether or some other liquid materials which are for improving thermal conductivity.

The heat dissipation body 200a is made of, for example, metal, graphite, ceramics or some other materials having heat dissipating capability. The heat dissipation body 200a has a first end 220a and a second end 230a that are opposite to each other. The heat dissipation body 200a has a second chamber 210a, and the second chamber 210a extends to the second end 230a from the first end 220a. The first end 220a and the second end 230a of the heat dissipation body 200a are adjacent to two sides of the heat absorbing body 100a that are opposite to each other. In detail, the heat dissipation body 200a is bent along a semi-circular arc S to be U-shaped. The first end 220a and the second end 230a of the heat dissipation body 200a are located at two sides of the heat absorbing body 100a that are opposite to each other.

One of the tubes 300a connects the heat absorbing body 100a and the first end 220a of the heat dissipation body 200a. Another tube 300a connects the heat absorbing body 100a and the second end 230a of the heat dissipation body 200a. The other tube 300a connects the heat absorbing body 100a and a middle-section 240a of the heat dissipation body 200a

The light source 30a is, for example, a light emitting diode or a tungsten lamp. The light source 30a is in thermal contact with the heat absorbing body 100a, adjacent to the first end 220a and the second end 230a of the heat dissipation body 200a, and opposite to the middle-section 240a of the heat dissipation body 200a with respect to the heat absorbing body 100a.

In this embodiment, the heat dissipation body 200a is a U-shaped heat dissipation body, and parts of the U-shaped heat dissipation body 200a surround a part of the periphery of the heat absorbing body 100a, allowing the phase-change heat dissipating device 20a to be oriented in different directions by being rotated by 180 degrees on a plane.

In addition, in this embodiment, the principle of the heat dissipation of the phase-change heat dissipating device 20a is similar to the principle of the heat dissipation of the phase-change heat dissipating device 20 in the first embodiment.

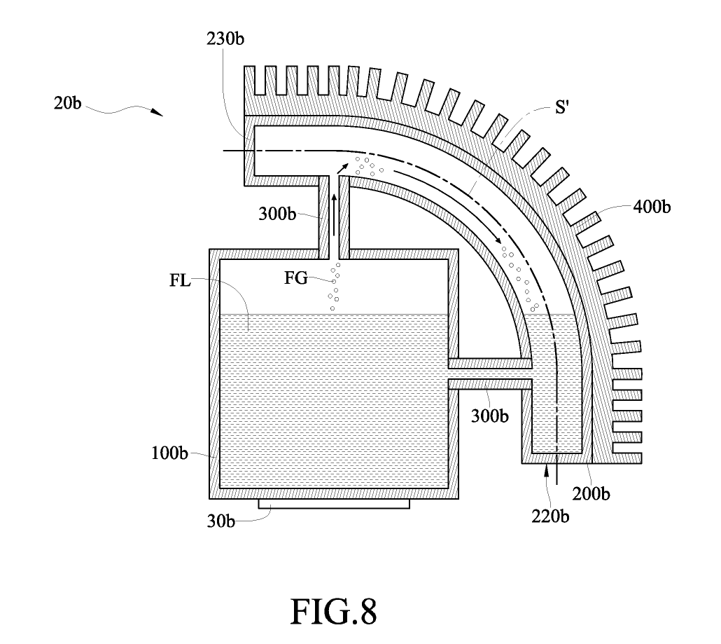

The aforementioned heat dissipation body 200a is bent along the semi-circular arc S, but the disclosure is not limited thereto. Please refer to FIG. 8, which is a cross-sectional view of the phase-change heat dissipating device and the light source according to a fourth embodiment of the disclosure. Since the fourth embodiment is similar to the third embodiment, the parts in the fourth embodiment which are similar to those of the third embodiment will not be further described.

In this embodiment, the heat dissipation body 200b is bent along a quarter-circle arc S to be L-shaped. Parts of the heat dissipation body 200b surround a part of the peripheral of the heat absorbing body 100b, the first end 220b and the second end 230b of the heat dissipation body 200b are located at two sides of the heat absorbing body 100b that are adjacent to each other, allowing the phase-change heat dissipating device 20b to be positioned in different directions by being rotated by 90 degrees on a plane.

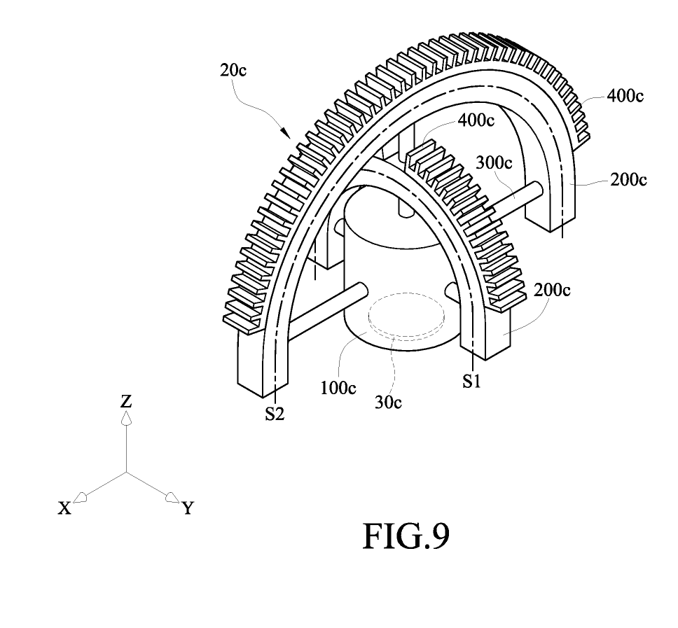

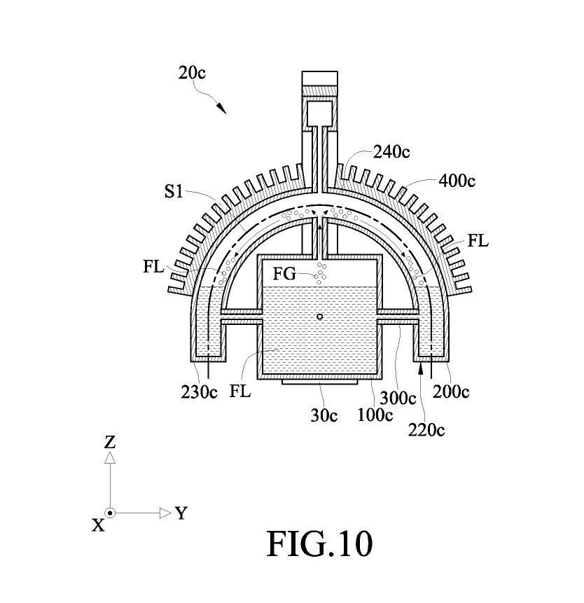

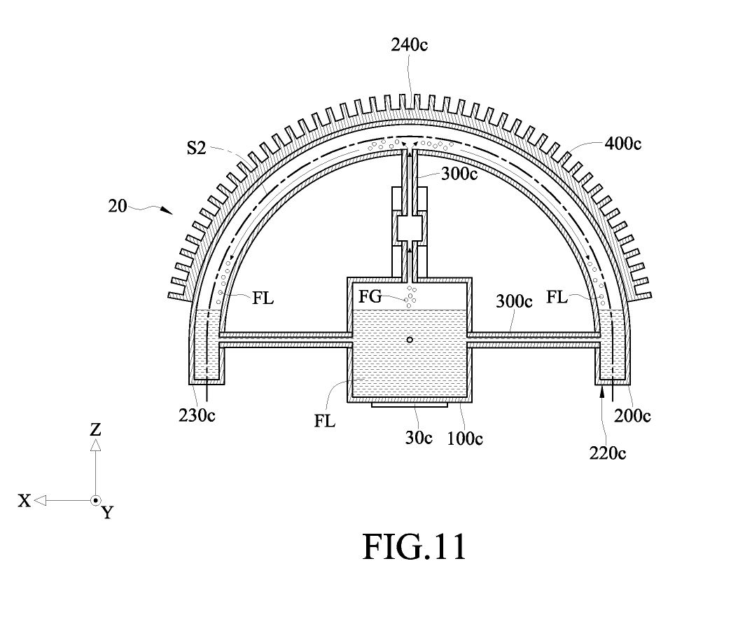

Please refer to FIGS. 9-11. FIG. 9 is a perspective view of the phase-change heat dissipating device and the light source according to a fifth embodiment of the disclosure. FIG. 10 and FIG. 11 are cross-sectional views of the phase-change heat dissipating device and the light source from different viewpoints according to the fifth embodiment of the disclosure. Since the fifth embodiment is similar to the third embodiment, the parts in the fifth embodiment which is similar to those of the third embodiment will not be further described.

In this embodiment, the quantity of the heat dissipation bodies 200c is two; the two heat dissipation bodies 200c are bent along arcs S1 and S2, respectively, to be U-shaped. Accordingly, two ends 220c and 230c of the heat dissipation body 200c that are opposite to each other and the middle-section 240c are located at different sides of the heat absorbing body 100c, respectively. In addition, the two arcs S1 and S2 lie on two planes which are substantially orthogonal to each other and not parallel to a light emitting surface of the light source 30c, allowing the phase-change heat dissipating device 20c to be suitable for being oriented in different directions by being rotated by 180 degrees on two planes that are orthogonal to each other.

In this embodiment, the phase-change heat dissipating device 20c has, for example, two U-shaped heat dissipation bodies 200c. In other embodiments, the phase-change heat dissipating device has one U-shaped heat dissipation body and one L-shaped heat dissipation body. Alternatively, the phase-change heat dissipating device has one U-shaped heat dissipation body and one cylindrical type heat dissipation body.

According to the phase-change heat dissipating device and the lamp as discussed above, one or multiple heat dissipation bodies completely or partially surround the peripheral of the heat absorbing body, allowing the phase-change heat dissipating device and the lamp to perform the cooling circulation automatically when the lamp is disposed in different positions or directions. Thus, the problem that the positions or directions of the conventional lamp being restricted is avoided.

What is claimed is:

1. A phase-change heat dissipating device, comprising:
a heat absorbing body for being in thermal contact with at least one heat source, and the heat absorbing body filled with a working fluid;
at least one heat dissipation body having a first end and a second end, and the first end and the second end of the at least one heat dissipation body being adjacent to two sides of the heat absorbing body that are different from each other, respectively; and
at least two tubes connecting the heat absorbing body and the at least one heat dissipation body, when parts of the at least one heat dissipation body are located higher than the heat absorbing body and the working fluid absorbs heat energy generated from the heat source, the working fluid is evaporated from a liquid phase to a gas phase and flows into the at least one heat dissipation body through one of the at least two tubes for dissipating heat, and the working fluid which is located in the at least one heat dissipation body is condensed from a gas phase into a liquid phase and flows to the heat absorbing body through the other one of the at least two tubes.

2. The phase-change heat dissipating device according to claim 1, wherein the first end and the second end of the at least one heat dissipation body are adjacent to two sides of the heat absorbing body that are adjacent to each other, one of the at least two tubes connects the heat absorbing body and the first end of the at least one heat dissipation body, and the other one of the at least two tubes connects the heat absorbing body and the second end of the at least one heat dissipation body.

3. The phase-change heat dissipating device according to claim 1, wherein the first end and the second end of the at least one heat dissipation body are adjacent to two sides of the heat absorbing body that are opposite to each other, respectively, one of the at least two tubes connects the heat absorbing body and the first end of the at least one heat dissipation body, and the other one of the at least two tubes connects the heat absorbing body and the second end of the at least one heat dissipation body.

4. The phase-change heat dissipating device according to claim 3, wherein the quantity of the at least two tubes is three, one of the tubes connects the heat absorbing body and the first end of the at least one heat dissipation body, another one of the tubes connects the heat absorbing body and the second end of the at least one heat dissipation body, and the other one of the tubes connects the heat absorbing body and a middle-section of the at least one heat dissipation body.

5. The phase-change heat dissipating device according to claim 1, wherein the heat dissipation body is bent along an arc.

6. The phase-change heat dissipating device according to claim 1, wherein the quantity of the at least one heat dissipation body is two, the two heat dissipation bodies are bent along two arcs, respectively, and the two arcs lie on two planes which are substantially orthogonal to each other, respectively.

7. The phase-change heat dissipating device according to claim 1, wherein the quantity of the at least one heat dissipation body is two, the two heat dissipation bodies are bent along two arcs, respectively, and the two arcs lie in two planes which are substantially orthogonal from each other, respectively.

8. The phase-change heat dissipating device according to claim 1, wherein at least one of the at least two tubes is located higher than a liquid level of the working fluid.

9. The phase-change heat dissipating device according to claim 1, further comprising a heat sink being in thermal contact with the at least one heat dissipation body.

10. A phase-change heat dissipating device, comprising:
a heat absorbing body for being in thermal contact with a heat source, and the heat absorbing body filled with a working fluid;
at least two heat dissipation bodies being adjacent to two sides of the heat absorbing body that are different from each other, respectively; and
a plurality of tubes connecting the heat absorbing body and the at least two heat dissipation bodies, when one of the at least two heat dissipation bodies is located higher than the heat absorbing body, and the working fluid absorbs heat energy generated from the heat source, the working fluid is evaporated from a liquid phase to a gas phase and flows into one of the at least two heat dissipation bodies through one of the plurality of tubes for dissipating heat, and the working fluid which is located in one of the at least two heat dissipation bodies is condensed from the gas phase into the liquid phase and flows to the heat absorbing bodies through one of the plurality of tubes.

11. The phase-change heat dissipating device according to claim 10, wherein the quantity of the at least two heat dissipation bodies is greater than three, and the heat dissipation bodies are adjacent to sides of the heat absorbing body that are opposite to each other, respectively.

12. A lamp, comprising:
a case having a space and a light transmitting part which is connected to the space;
at least one phase-change heat dissipating device disposed in the space, and the at least one phase-change heat dissipating device comprising:
a heat absorbing body filled with a working fluid;
at least one heat dissipation body having a first end and a second end, and the first end and the second end of the heat dissipation body being adjacent to two sides of the heat absorbing body that are different from each other, respectively; and
at least two tubes connecting the heat absorbing body and the at least one heat dissipation body; and
at least one light source being in thermal contact with the heat absorbing body, and the light source being exposed from the light transmitting part, when parts of the at least one heat dissipation body are located higher than the heat absorbing body, and the working fluid absorbs heat energy generated from the light source, the working fluid is evaporated from a liquid phase to a gas phase, and flows into the at least one heat dissipation body through one of the at least two tubes for dissipating heat, and the working fluid which is located in the at least one heat dissipation body is condensed from the gas phase into the liquid phase and flows to the heat absorbing body through the other one of the at least two tubes.

13. A lamp, comprising:
a case having a space and a light transmitting part which is disposed on a side of the space;
at least one phase-change heat dissipating device disposed in the space, the at least one phase-change heat dissipating device comprising:
a heat absorbing body filled with a working fluid;
at least two heat dissipation bodies being adjacent to two sides of the heat absorbing body that are different from each other, respectively; and
a plurality of tubes connecting the heat absorbing body and the at least two heat dissipation bodies; and
at least one light source being in thermal contact with the heat absorbing body, and the light source being exposed from the light transmitting part, when parts of one of the at least two heat dissipation bodies are located higher than the heat absorbing body, and the working fluid absorbs heat energy generated from the light source, the working fluid is evaporated from a liquid phase to a gas phase and flows into one of the at least two heat dissipation bodies through one of the plurality of tubes for dissipating heat, and the working fluid which is located in one of the at least two heat dissipation bodies is condensed from the gas phase into the liquid phase and flows to the heat absorbing bodies through one of the plurality of tubes.
